(19) United States
(12) Patent Application Publication
(10) Pub. No.: US 2019/0080985 A1
(43) Pub. Date: Mar. 14, 2019

(54) LIQUID-COOLED TYPE COOLING DEVICE

(71) Applicant: KEIHIN THERMAL TECHNOLOGY CORPORATION, Oyama-shi (JP)

(72) Inventors: Naohisa HIGASHIYAMA, Oyama-shi (JP); Takashi HIRAYAMA, Oyama-shi (JP)

(73) Assignee: KEIHIN THERMAL TECHNOLOGY CORPORATION, Oyama-shi (JP)

(21) Appl. No.: 16/128,523

(22) Filed: Sep. 12, 2018

(30) Foreign Application Priority Data
Sep. 14, 2017 (JP) 2017-177011

(51) Int. Cl. H01L 23/473; F28F 3/02; F28D 15/02

(52) U.S. Cl. CPC H01L 23/473; H01L 23/3675; F28D 15/0233; F28F 3/027

(57) ABSTRACT

A liquid-cooled type cooling device includes first and second casings which are capable of being divided in a vertical direction. On a bottom wall part of the second casing, which faces toward fins that are accommodated therein, a plurality of slits are formed, which are recessed in a direction away from the fins. The slits extend in a straight line along a widthwise direction of the second casing substantially perpendicular to a direction in which a coolant medium flows, and are disposed in plurality while being separated at equal intervals along the flow direction.

### CROSS-REFERENCE TO RELATED APPLICATION

This application is based upon and claims the benefit of priority from Japanese Patent Application No. 2017-177011 filed on Sep. 14, 2017, the contents of which are incorporated herein by reference.

### BACKGROUND OF THE INVENTION

### Field of the Invention

The present invention relates to a liquid-cooled type cooling device, which is capable of cooling electronic components by heat exchange with a coolant medium that flows through a plurality of flow paths.

### Description of the Related Art

Conventionally, for example, as disclosed in Japanese Laid-Open Patent Publication No 2012-038010, a cooling device for cooling an electronic component, for example, a semiconductor device that generates heat, is known. Such a cooling device includes a casing, and a plurality of fins accommodated in the interior of the casing. The electronic component is disposed on a lower surface of the casing on an outer side thereof, together with the fins being disposed in contact with the lower surface in the interior of the casing.

On the other hand, a projecting member that projects toward the interior is formed on an upper surface of the casing, and a portion of the coolant medium flowing between the fins and the upper surface collides with the projecting member and is deflected, and enters in between the fins, whereby the coolant medium of a low temperature that flows in the vicinity of the upper surface is guided toward the side of the lower surface of the casing on which the electronic component is mounted, so as to increase the cooling efficiency thereof.

### SUMMARY OF THE INVENTION

However, in the above-described cooling device, flow resistance increases due to the coolant medium colliding against the projecting member, and together therewith, since only a portion of the coolant medium inside the casing can be made to flow toward the side of the fins, the cooling efficiency of the electronic component cannot be sufficiently increased.

A general object of the present invention is to provide a liquid-cooled type cooling device, which is capable of further enhancing cooling efficiency while suppressing flow resistance of the coolant medium.

The present invention is characterized by a liquid-cooled type cooling device adapted to cool an electronic component disposed on a casing and associated with generation of heat, by heat exchange with a coolant medium, comprising the casing having a supply port to which the coolant medium is supplied and a discharge port from which the coolant medium is discharged, and fins accommodated inside the casing, wherein the casing comprises:

a first wall part on which the electronic component is mounted; and

a second wall part facing toward the first wall part with the fins interposed therebetween; and

on a surface facing toward the fins on the second wall part, a recessed portion is formed which is recessed in a direction away from the fins.

According to the present invention, on the casing that constitutes the liquid-cooled type cooling device, electronic components, which are associated with generation of heat, are mounted on the first wall part of the casing. The second wall part is formed so as to face toward the first wall part, with the fins, which are accommodated inside the casing, being interposed therebetween, and the recessed portion, which is recessed in a direction away from the fins, is formed in the second wall part in a surface thereof facing toward the fins.

Accordingly, when the coolant medium, which is supplied into the casing through the supply port, flows to the discharge port on a downstream side along the fins, a portion of the coolant medium flows into the recessed portion, and flows so as to return again into the flow path. Thus, the refrigerant can be made to flow in a reverse manner and thereby generate convection from the side of the second wall part to the side of the first wall part inside the casing.

As a result, the coolant medium on the side of the first wall part, which is heated by heat exchange with the electronic components, and the coolant medium that is cooled on the side of the second wall part can be suitably mixed together, and by lowering the temperature of the coolant medium on the side of the first wall part, it is possible to improve the cooling efficiency of the electronic components.

The above and other objects, features, and advantages of the present invention will become more apparent from the following description when taken in conjunction with the accompanying drawings, in which preferred embodiments of the present invention are shown by way of illustrative example.

### BRIEF DESCRIPTION OF THE DRAWINGS

FIG. 1 is an overall cross-sectional view of a liquid-cooled type cooling device according to an embodiment of the present invention;

FIG. 2 is an exploded perspective view of the liquid-cooled type cooling device shown in FIG. 1;

FIG. 3 is an enlarged cross-sectional view showing the vicinity of a bottom wall part of a second casing in the liquid-cooled type cooling device of FIG. 1;

FIG. 4 is an overall plan view of the second casing in the liquid-cooled type cooling device shown in FIG. 1;

FIG. 5A is an overall plan view of the second casing having slits therein according to a first modification; and

FIG. 5B is an overall plan view of the second casing having slits therein according to a second modification.

### DESCRIPTION OF THE PREFERRED EMBODIMENTS

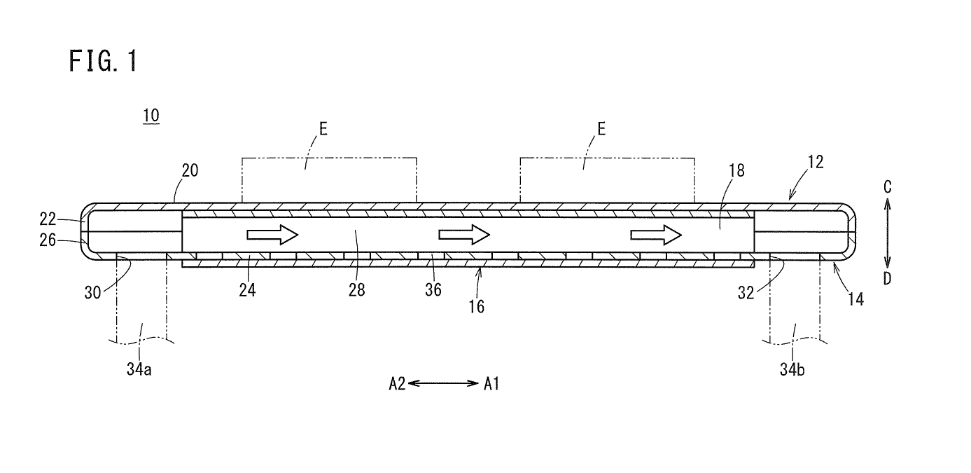

As shown in FIGS. 1 to 3, a liquid-cooled type cooling device 10 includes first and second casings (casings) 12, 14 which are capable of being separated vertically, a cover plate 16 that covers a portion of the second casing 14, and fins 18 accommodated in the interior of the first and second casings 12, 14.

The first and second casings 12, 14 are formed in substantially the same shape from a metal material. The first casing 12 is constituted from a flat top wall part (first wall part) 20 and a first side wall part 22 erected on an outer edge of the top wall part 20, and electronic components E made of semiconductors or the like which are required to be cooled and are mounted on an upper surface of the top wall part 20. Concerning the electronic components E, for example, two electronic components E are mounted along a longitudinal direction (in the direction of arrows A1, A2) of the first casing 12.

As shown in FIGS. 1 to 4, the second casing 14 is constituted from a flat bottom wall part (second wall part) 24, and a second side wall part 26 erected on an outer edge portion of the bottom wall part 24. Additionally, the bottom wall part 24 is formed in substantially the same shape as the top wall part 20 of the first casing 12, and together therewith, in a state in which an end of the second side wall part 26 is placed in contact with an end of the first side wall part 22 on the first casing 12, the ends are connected together, for example, by brazing or the like.

Consequently, the top wall part 20 and the bottom wall part 24 are substantially parallel to each other, and a space, which is formed inside the first and second casings 12, 14, serves as a flow path 28 through which the coolant medium flows.

Further, in the bottom wall part 24, at one end portion and another end portion along the longitudinal direction (the direction of arrows A1, A2) thereof, a supply port 30 to which the coolant medium is supplied, and a discharge port 32 from which the coolant medium is discharged open respectively, and pipes 34a, 34b for supply and discharge of the coolant medium are respectively connected substantially perpendicularly with respect to the bottom wall part 24. More specifically, the coolant medium flows in the longitudinal direction (the direction of the arrow A1 in FIG. 1) in the first and second casings 12, 14 from the supply port 30 to the discharge port 32.

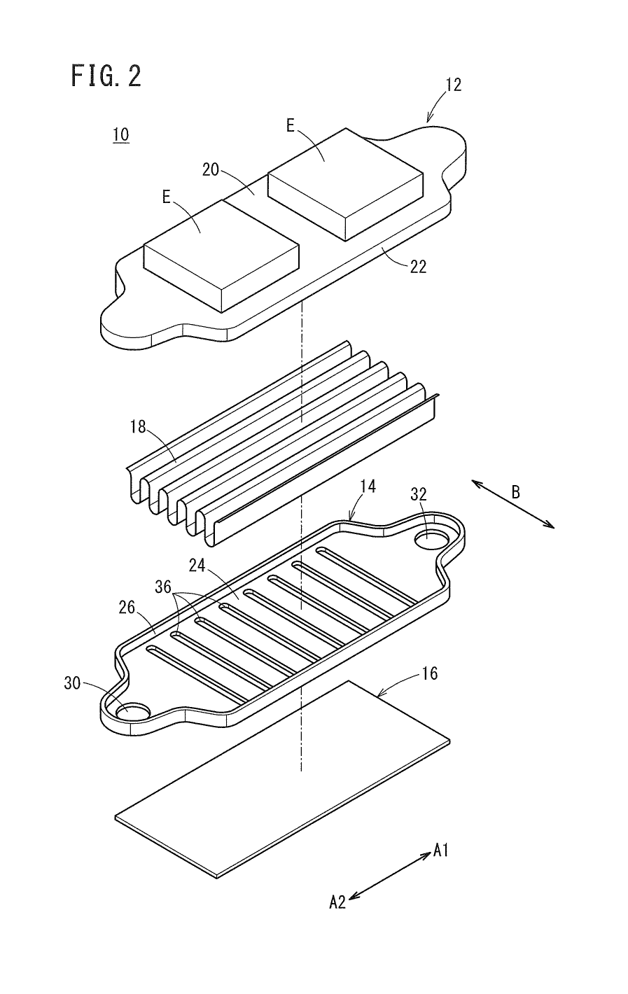

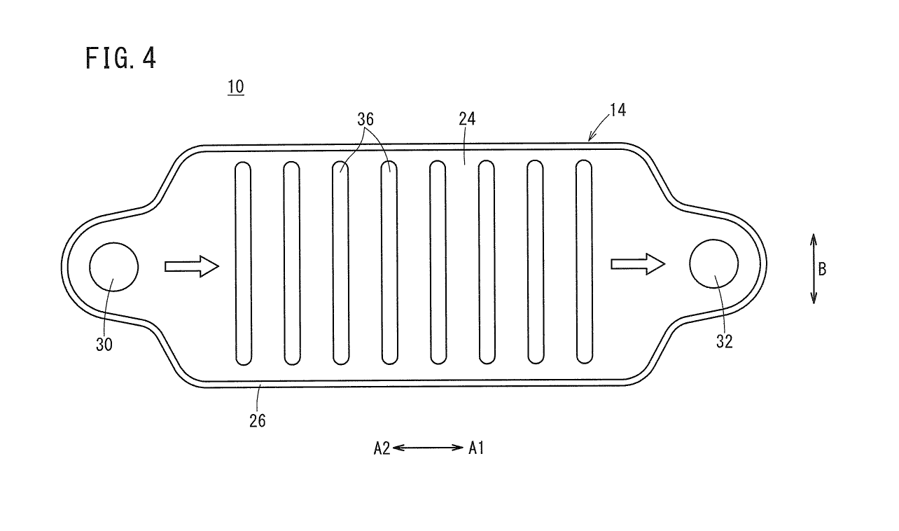

Furthermore, slits 36 are formed in the bottom wall part 24 so as to extend in a widthwise direction (the direction of the arrow B in FIGS. 2 and 4) perpendicular to the longitudinal direction (the direction of the arrow A1), which is the direction in which the coolant medium flows. The slits 36 are formed, for example, with a rectangular cross section penetrating through the bottom wall part 24, and are disposed in plurality so as to be spaced apart at equal intervals from each other along the longitudinal direction (the direction of the arrows A1, A2). The slits 36 are formed in a straight line shape extending from the vicinity of one second side wall part 26 to another second side wall part 26 along the widthwise direction of the second casing 14.

The cover plate 16 is disposed in abutment against the bottom wall part 24 of the second casing 14 from below, to thereby bring about a state in which the plurality of slits 36 are all covered. In addition, the cover plate 16 is affixed with respect to the bottom wall part 24 of the second casing 14, for example, by brazing, so that the slits 36 are placed in a state of non-communication with the exterior of the second casing 14.

The fins 18, for example, are formed by bending a thin plate of an aluminum material or the like so as to have a wave-like shape in cross section, and the fins 18 are disposed so as to alternately contact the top wall part 20 of the first casing 12 and the bottom wall part 24 of the second casing 14 along the widthwise direction of the first and second casings 12, 14, together with being formed to extend along the longitudinal direction (the direction of arrows A1, A2) of the first and second casings 12, 14 with a wave-like shape in cross section. Additionally, the coolant medium flows in the flow path 28 in the longitudinal direction (the direction of arrow A1) along the plurality of fins 18 in the interior of the first and second casings 12, 14.

The liquid-cooled type cooling device 10 according to the embodiment of the present invention is basically constructed in the manner described above. Next, operations and effects of the liquid-cooled type cooling device 10 will be described.

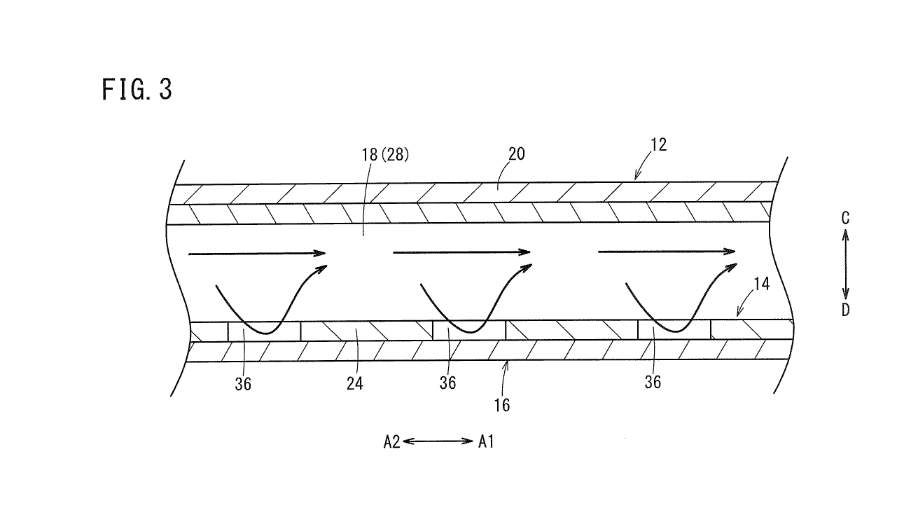

Initially, the coolant medium is supplied from a non-illustrated coolant medium supply means through a pipe 34a to the supply port 30, and flows in the flow path 28 along the plurality of fins 18 to a downstream side of the first and second casings 12, 14. In addition, as shown in FIG. 1, the coolant medium flows in a straight line along the plurality of fins 18 toward the side of the discharge port 32 (in the direction of the arrow A1), and simultaneously therewith, as shown in FIG. 3, portions of the coolant medium flow into the slits 36, which are recessed downward in the direction of gravity (in the direction of the arrow D), and flow out from the slits 36 again in an upward direction (the direction of the arrow C) in a reversely directed flow, thereby generating convection.

The coolant medium that flows in the first and second casings 12, 14 and the heat generated by the electronic components E undergo heat exchange via the fins 18 and the top wall part 20 of the first casing 12 with which the fins 18 are in contact, and the electronic components E are cooled while simultaneously the coolant medium is heated.

More specifically, due to the slits 36, by deflecting the coolant medium flowing in the vicinity of the bottom wall part 24 of the second casing 14 in an upward direction (in the direction of the arrow C), the coolant medium on the side of the first casing 12, which is heated by the electronic components E, and the coolant medium on the side of the second casing 14, which is cooled to a relatively cooler temperature, are suitably mixed to thereby lower the temperature of the coolant medium on the side of the first casing 12, and effectively cool the electronic components E.

Lastly, the coolant medium which was subjected to heat exchange flows to the discharge port 32 on the downstream side along the fins 18, and is discharged from the discharge port 32 into the pipe 34b. Moreover, the coolant medium is again cooled externally of the first and second casings 12 and 14, and after having been cooled again, is supplied and recirculated to the supply port 30 from the coolant medium supply means.

In the foregoing manner, according to the present embodiment, in the first and second casings 12, 14 that constitute the liquid-cooled type cooling device 10, the plurality of slits 36 are formed in the bottom wall part 24 of the second casing 14 in facing relation to the fins 18, and the slits 36 are recessed with respect to the bottom wall part 24, and extend so as to be substantially perpendicular to the direction in which the coolant medium flows (in the direction of the arrow A1). Consequently, a portion of the coolant medium, which flows to the downstream side (in the direction of the arrow A1) through the flow path 28 of the first and second casings 12, 14, flows into the slits 36, and flows so as to return again into the flow path 28. Thus, the coolant medium can be deflected in an upward direction (the direction of the arrow C) and made to flow in a reverse manner thus generating convection inside the flow path 28.

As a result, the coolant medium on the side of the first casing 12, which is heated by heat exchange with the circuit components E, and the coolant medium that is cooled on the side of the second casing 14 can be suitably mixed together, whereby the coolant medium on the side of the first casing 12 is suitably cooled, and by cooling the electronic components E mounted on the first casing 12, the cooling efficiency of the electronic components E can be enhanced.

Further, since the plurality of slits 36 do not project out into the flow path 28 through which the coolant medium flows inside the first and second casings 12, 14, compared to the cooling device of the conventional art in which a projecting member projects toward the interior from an upper surface of the casing, an increase in flow resistance of the coolant medium is suppressed, and the coolant medium can be made to flow smoothly.

Furthermore, by providing the plurality of slits 36 along the flow direction of the coolant medium, the coolant medium is continuously deflected in an upward direction (in the direction of the arrow C) along the flow direction of the coolant medium, thereby making it possible to generate convection inside the flow path 28.

Further still, by the slits 36 being extended in a straight line shape along the widthwise direction (the direction of the arrow B) of the second casing 14, the coolant medium can also be made to move back and forth in the widthwise direction (the direction of the arrow B) through the slits 36. As a result, by suitably mixing the coolant medium at the center in the widthwise direction where the electronic components E are mounted and the coolant medium on the outer sides in the widthwise direction (in the direction of the arrow B), the electronic components E can be cooled by a coolant medium having a lower temperature, and it is possible to further enhance the cooling efficiency.

Still further, as shown in FIG. 4, by disposing the plurality of slits 36 at equal intervals along the direction (the direction of the arrow A1) in which the coolant medium flows, the coolant medium can be subjected to convection and mixed uniformly along the direction of flow.

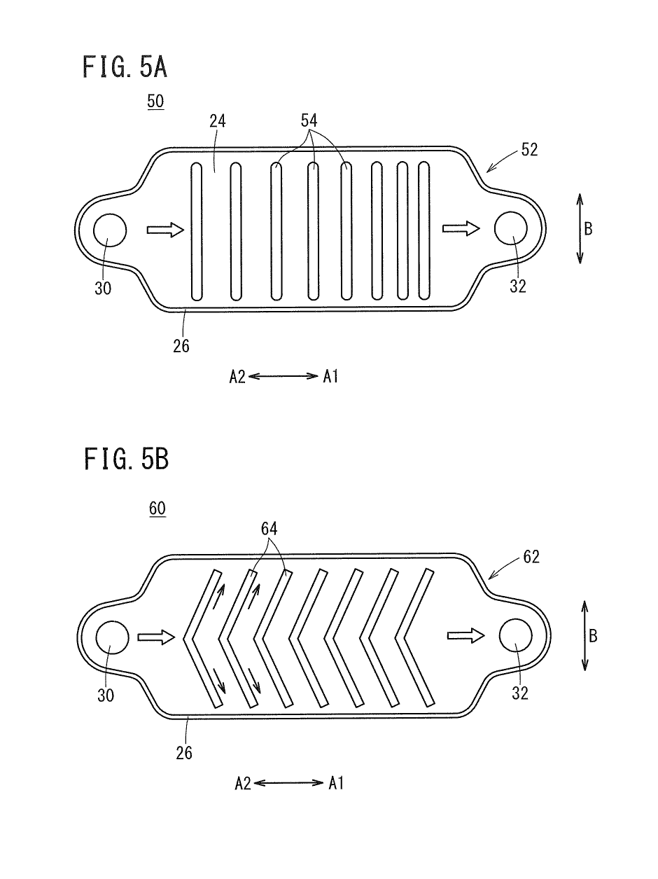

Furthermore, as in the second casing 52 of the liquid-cooled type cooling device 50 shown in FIG. 5A, the slits (recessed portions) 54 are arranged at non-equal intervals in a manner so that the pitch between the slits 54 becomes smaller toward the downstream side along the direction of flow. Accordingly, the coolant medium on the downstream side (in the direction of the arrow A1), the temperature of which rises in comparison with that on the upstream side (in the direction of the arrow A2) due to heat exchange with the electronic components E, can be actively subjected to convection and mixed, and it is possible to enhance the cooling efficiency of the electronic component E that is arranged on the downstream side.

On the other hand, the slits 36 are not limited to a case of extending in straight line shapes along the widthwise direction (the direction of the arrow B) of the second casing 14. For example, as in the second casing 62 of the liquid-cooled type cooling device 60 shown in FIG. 5B, slits 64 may be provided that are V-shaped in cross section, and which are inclined at a predetermined angle so as to expand outwardly in the widthwise direction (in the direction of the arrow B) toward the downstream side (in the direction of the arrow A1) from the center in the widthwise direction.

In accordance with this feature, by utilizing the flow from the upstream side to the downstream side, the coolant medium that has flowed into the slits 64 can be made to flow from the center in the widthwise direction of the slits 64 to the outer sides in the widthwise direction, and therefore, the coolant medium at the center in the widthwise direction, which is heated by heat exchange with the electronic components, can be made to flow to the outer sides in the widthwise direction (in the direction of the arrow B), and to be mixed and undergo cooling with the coolant medium on the outer sides in the widthwise direction. As a result, by cooling the electronic components E with the coolant medium that is mixed with the coolant medium on the outer sides, and which is lowered in temperature thereby, the cooling efficiency can be enhanced.

The liquid-cooled type cooling device according to the present invention is not limited to the above-described embodiments, and it goes without saying that various modified or additional configurations could be adopted therein without departing from the essence and gist of the present invention.

What is claimed is:

1. A liquid-cooled type cooling device adapted to cool an electronic component disposed on a casing and associated with generation of heat, by heat exchange with a coolant medium, comprising the casing having a supply port to which the coolant medium is supplied and a discharge port from which the coolant medium is discharged, and fins accommodated inside the casing;
wherein the casing comprises:
a first wall part on which the electronic component is mounted; and
a second wall part facing toward the first wall part with the fins interposed between the first wall part and the second wall part; and
on a surface facing toward the fins on the second wall part, a recessed portion is formed which is recessed in a direction away from the fins.

2. The liquid-cooled type cooling device according to claim 1, wherein the recessed portion is formed to be substantially perpendicular with respect to a direction in which the coolant medium flows.

3. The liquid-cooled type cooling device according to claim 1, wherein the recessed portion is formed to be inclined at a predetermined angle with respect to a direction in which the coolant medium flows.

4. The liquid-cooled type cooling device according to claim 1, wherein a plurality of the recessed portions are disposed along a direction in which the coolant medium flows, and are arranged mutually at equal intervals from each other.

5. The liquid-cooled type cooling device according to claim 1, wherein a plurality of the recessed portions are disposed along a direction in which the coolant medium flows, and are arranged so as to be spaced apart at non-equal intervals.

6. The liquid-cooled type cooling device according to claim 1, wherein the second wall part is a bottom wall of the casing.

7. The liquid-cooled type cooling device according to claim 1, wherein the recessed portion penetrates through the second wall part, and is covered by a cover member that abuts against the casing.
